(19) United States
(12) Patent Application Publication
(10) Pub. No.: US 2002/0014705 A1
(43) Pub. Date: Feb. 7, 2002

(54) Semiconductor device and manufacturing method of same

(76) Inventors: Toshiya Ishio, Nabari-shi (JP); Hiroyuki Nakanishi, Kitakatsuragi-gun (JP); Katsunobu Mori, Nara-shi (JP)

Correspondence Address: NIXON & VANDERHYE P.C., 8th Floor, 1100 North Glebe Rd., Arlington, VA, 22201-4714, US

(21) Appl. No.: 09/883,366

(22) Filed: Jun. 19, 2001

(30) Foreign Application Priority Data
Aug. 1, 2000 (JP) 2000-233551

(51) Int. Cl. H01L 21/44; H01L 23/48; H01L 23/52; H01L 29/40

(52) U.S. Cl. 257/784; 438/617

(57) ABSTRACT

An semiconductor device of the present invention, while the semiconductor device is provided with a main conductor layer, which has an end electrically connected to an electrode pad, an insulating layer, which has an opening section on the main conductor layer, and a protrudent electrode, which is electrically connected to the main conductor layer via the opening section, is further provided with a metal layer in the opening section on the main conductor layer, so that the metal layer is located between the conductor layer and the protrudent electrode. This provides a metal layer in the opening section on the main conductor layer. Thus no gap is formed between the insulating layer and the main conductor layer, even when the metal layer forms an alloy layer with a metal structuring the protrudent electrode. Thereby, water condensation in the gap is prevented. Thus, provided is a semiconductor device, which can ensure high connection reliability.

### FIELD OF THE INVENTION

The present invention relates to a semiconductor device having a structure in which a protrudent electrode for external connection is repositioned, and especially relates to a semiconductor device which can prevent deterioration of reliability, even if a layer, which is in contact with the protrudent electrode is made of a metal having good wetting properties, and to a manufacturing method of same.

### BACKGROUND OF THE INVENTION

Electronic devices are provided with a pad for establishing electrical connection with an external wire. But a position of the pad to be formed, (or a formation position of the pad) differs according to differences in packing methods for a large scale integrated circuit (an LSI) chip. Thus, it is necessary to predetermine the formation position and a layout of the pad in accordance with the needs of the packing methods. However, this increases variety in products, thereby leading to complication and higher cost of management of the products. Thus, the products will be more expensive. In view of this, a pad repositioning structure has been contrived. With the pad repositioning structure, even if different packaging methods of the LSI chip are employed, the LSI chip can be used, because the pad position is repositioned after the formation of the pad of the LSI chip in the predetermined position.

For example, in a structure disclosed in Japanese Un-examined Patent Publication No. 10-261663 (published on Sep. 29, 1998), as shown in FIG. 9, an electrode pad 102 and other elements (not shown) are formed on a semiconductor substrate 101. Further, on the semiconductor substrate 101, a first protective insulating film 103 is formed in a manner that the electrode pad 102 is covered with the first protective insulating film 103. The first protective insulating film 103 is provided with a first opening section 103a for exposing the electrode pad 102. On the first protective insulating film 103, provided is an outgoing line 109 which is structured with a metal layer 104, a main conductor layer 105, and a top layer 106. On the top layer 106 and on the sides of the outgoing line 109, formed is a second protective insulating film 107 which has a second opening section 107a on the top layer 106. A region of the outgoing line 109 exposed through the second opening section 107a iS used as a pad. A bump 108 made of Sn—Pb solder is formed on the region.

An end of the outgoing line 109 is connected to the electrode pad 102. The outgoing line 109 has a region located far from the electrode pad 102. A part of the region is exposed, as the pad, though the second opening section 107a. Moreover, the main conductor 105 is made of a metal with high conductivity, such as Cu, while the top layer 106 are produced from platinum group elements, like Pd, Pt, Ro and the like.

Talking about its manufacturing method, firstly, the first protective insulating film 103 is formed on the semiconductor substrate 101 provided with the electrode pad 102. The first opening section 103a is formed on the first protective insulating film 103 so as to expose the electrode pad 102. The metal layer 104 is formed in the first opening section 103a and on the first protective insulating film 103, by spattering or vapor deposition. Subsequently, a resist is applied on the metal layer 104. An opening section is made in the resist so that exposure and development of the resist prepares an area in which the outgoing line 109 is formed.

In the opening section of the resist, the main conductor layer 105 is produced from a metal, such as Cu, by treatments, such as electroplating. By employing the same film-making method as the main conductor layer 105, a film of a metal belong to the platinum group is formed over the entire top surface of the main conductor layer 105, so that the top layer 106 is formed. Then, the resist is peeled off by using a solvent. Further, the metal layer 104 is removed by an acid etching solution or an alkaline one, while the main conductor layer 105 and the top layer 106 are used as photo masks. Subsequently, the second protective insulating film 107 is produced from polyimide and the like, on the top and side surfaces of the outgoing line 109. In the manner to expose a part of the top surface of the top layer 106, the second opening section 107a is formed in the second protective insulating film 107 by patterning. In the second opening section 107a, formed as a terminal for external connection is the bump 108 made of Sn—Pb solder.

However, the conventional structure has the following problems.

In terms of the Sn—Pb solder, it was found in a test for wetting properties of the solder that Au-surface sample showed better wetting properties than Pd-surface sample, even though Pb was a metal in the platinum group.

The test on the wetting properties of the solder was carried out in the following manner. Firstly, a test sample was soaked in rosin flux for 5 seconds, then, was soaked in a solder bath at 230° C. for 5 seconds. After that, alcohol washing was applied to the sample. Thereafter, its lead surface was observed by a stereo microscope (×20).

The result showed that the Pd-surface sample had Grade 3, in which 92% or more of the lead surface was coated with the solder, while the Au-surface sample was Grade 5 where 98% or more of the lead surface was coated with the solder.

In the above arrangement, where the top layer 106 is formed with the metal belonging to the platinum group, the bump 108 made of a metal having Sn, for example the Sn—Pb solder, as its main component has poor wetting properties at the junction between the top layer 106 and the bump 108. Because of this, high connection reliability cannot be ensured in a semiconductor device that has the structure in which provided is the bump 108 as the external connection terminal. Therefore, it is necessary to use, as a raw material of the top layer 106, a metal that further improves the wetting properties of the Sn—Pb solder.

On the other hand, the Sn—Pb solder can attain excellent wetting properties by combining with Au, instead of a metal in the platinum group. But, this combination is accompanied with the following problems.

For example, a copper wire is formed on an integrated circuit (IC) wafer, then the entire wire is plated with Au. Further, a protective insulating film is formed thereon. An opening section is made in the protective insulating film on a region where the wire forms a terminal (an external connection terminal) for external connection. A bump of Sn—Pb solder is formed in the opening section. In this case, good wetting properties of the Sn—Pb solder with respect to the gold (Au) causes a phenomenon that the gold, which is located in the vicinity of where the Sn—Pb solder is formed, is also diffused into the Sn—Pb solder. This produces a gap between an interface where the gold and the protective insulator film meet together in the vicinity of the Sn—Pb solder. Water will be condensed in the gap. Thereby, the connection reliability of the semiconductor device is spoiled to a large extent, while the Sn—Pb solder becomes fragile because its good wetting properties results in excessive diffusion of Au from the surroundings.

The present invention, which is contrived in view of the above problems, has an object to provide a semiconductor device which can prevent deterioration of connection reliability due to the gap formation in the vicinity of the external connection terminal, while good connection reliability of the external connection terminal is ensured by the use of a metal of good wetting properties.

### SUMMARY OF THE INVENTION

An object of the present invention is to provide a semiconductor device and its manufacturing method, which can prevent deterioration of connection reliability due to gap formation in a vicinity of an external connection terminal, even when a metal having good wetting properties is used as an external connection terminal.

In order to attain the object, a semiconductor device of the present invention is provided with a main conductor layer, which has an end that is electrically connected to an electrode pad, an insulating layer, which has an opening section on the main conductor layer, and a protrudent electrode electrically connected to the main conductor layer via the opening section, the semiconductor device further including a metal layer provided on the main conductor layer in the opening section so that the metal layer is provided between the main conductor layer and the protrudent electrode.

In the above arrangement, the metal layer is disposed on the part of the main conductor layer in the opening section, that is, in the location between the main conductor layer and the protrudent electrode. Therefore, no gap is produced between the insulating layer and the main conductor layer, even when the good wetting properties of the metal layer with respect to the metal structuring the protrudent electrode result in diffusion of the metal layer into the metal structuring the protrudent electrode. The semiconductor device, which can ensure the high connection reliability, is provided by this arrangement, which prevents the water condensation in the gap formed between the insulating layer and the main conductor layer, and avoids connection failure caused by the water condensation.

In order to attain the object, a manufacturing method of a semiconductor device of the present invention includes the steps of (1) forming a foundation metal layer on a semiconductor substrate on which formed are a plurality of electrode pads and a first insulating layer having first opening sections on the electrode pads, (2) forming a photosensitive first resist on the foundation metal layer, (3) forming, in the first resist, a plurality of first resist opening sections for exposing the electrode pads, (4) forming a main conductor layer in the first resist opening sections, (5) removing the first resist, (6) removing the foundation metal layer by use of the main conductor layer as a photo mask, (7) forming a photosensitive second insulating layer so that the second insulating layer covers the first insulating layer and the main conductor layer, (8) forming second opening sections in regions of the second insulating layer, which covers the top surface of the main conductor layer, so that the main conductor layer is exposed therethrough, (9) forming a metal layer on main conductor layer in the second opening sections, and (10) forming protrudent electrodes on the metal layer.

With the above manufacturing method, the metal layer can be formed only in the second opening section, by the step of forming second opening sections in regions of the second insulating layer, which covers the top surface of the main conductor layer, so that the main conductor layer is exposed therethrough, and by the step of forming a metal layer on main conductor layer in the second opening sections. This prevents the gap formation between the insulating layer and the main conductor layer, even when the metal layer, which has the good wetting properties with respect to the metal structuring the protrudent electrode, is diffused into the metal structuring the protrudent electrode. This prevents the water condensation in the gap formed between the insulating layer and the main conductor layer, and avoids connection failure caused by the water condensation.

In order to attain the object, a manufacturing method of a semiconductor device of the present invention includes the steps of (1) forming a foundation metal layer on a semiconductor substrate on which formed are a plurality of electrode pads and a first insulating layer having first opening sections on the electrode pads, (2) forming a photosensitive first resist on the foundation metal layer, (3) forming, in the first resist, a plurality of first resist opening sections for exposing the electrode pads, (4) forming a main conductor layer in the first resist opening sections, (5) removing the first resist, (6) removing the foundation metal layer by use of the main conductor layer as a photo mask, (7) forming a second insulating layer so that the second insulating layer covers the first insulating layer and the main conductor layer, (8) forming a second resist on the second insulating layer, (9) forming, in the second resist, a plurality of second resist opening sections for exposing the main conductor layer, (10) forming second opening sections in regions of the second insulating layer, which covers a top surface of the main conductor layer, by use of the second resist as a photo mask, so that the main conductor layer is exposed therethrough, (11) forming a metal layer on the main conductor layer in the second opening sections, (12) removing the second resist, and (13) forming protrudent electrodes on the metal layer.

With the above manufacturing method, by the step of forming second opening sections in regions of the second insulating layer, which covers a top surface of the main conductor layer, by use of the second resist as a photo mask, so that the main conductor layer is exposed therethrough, and by the step of forming a metal layer on the main conductor layer in the second opening sections, the metal layer can be formed only in the second opening section. This prevents the gap formation between the insulating layer and the main conductor layer, even when the metal layer, which has the good wetting properties with respect to the metal structuring the protrudent electrode, is diffused into the metal structuring the protrudent electrode. This prevents the water condensation in the gap formed between the insulating layer and the main conductor layer, and avoids the connection failure caused by the water condensation. Moreover, the step of removing the second resist is employed after the step of forming the metal layer on the region of the main conductor layer in the second opening section. This allows the second insulating layer to be covered with the second resist at the time of the formation of the metal layer. This protects the second insulating layer from being polluted when soaked in chemicals, such as a plating solution.

For a fuller understanding of the nature and advantages of the invention, reference should be made to the ensuing detailed description taken in conjunction with the accompanying drawings.

### BRIEF DESCRIPTION OF THE DRAWINGS

FIG. 1 is a sectional view showing a structure of main sections of a semiconductor device of a first embodiment of the present invention.

In FIGS. 2(a) through 2(f), shown is a process flow diagram illustrating a manufacturing process of the semiconductor device.

In FIGS. 3(a) through 3(c), shown is a process flow diagram illustrating a part of another manufacturing process of the semiconductor device.

FIG. 4 is a sectional view showing a structure of main sections of a semiconductor device of a second embodiment of the present invention.

In FIGS. 5(a) through 5(f), shown is a process flow diagram illustrating a manufacturing process of the semiconductor device of the second embodiment of the present invention.

FIG. 6 is a sectional view showing a structure of main sections of another semiconductor device of the second embodiment of the present invention.

In FIGS. 7(a) through 7(c), shown is a process flow diagram illustrating a manufacturing process of the another semiconductor device shown in FIG. 6.

In FIGS. 8(a) through 8(d), shown is a process flow diagram illustrating another manufacturing process of the another semiconductor device shown in FIG. 6.

FIG. 9 is a sectional view showing s structure of main sections of a conventional semiconductor device.

### DESCRIPTION OF THE EMBODIMENTS

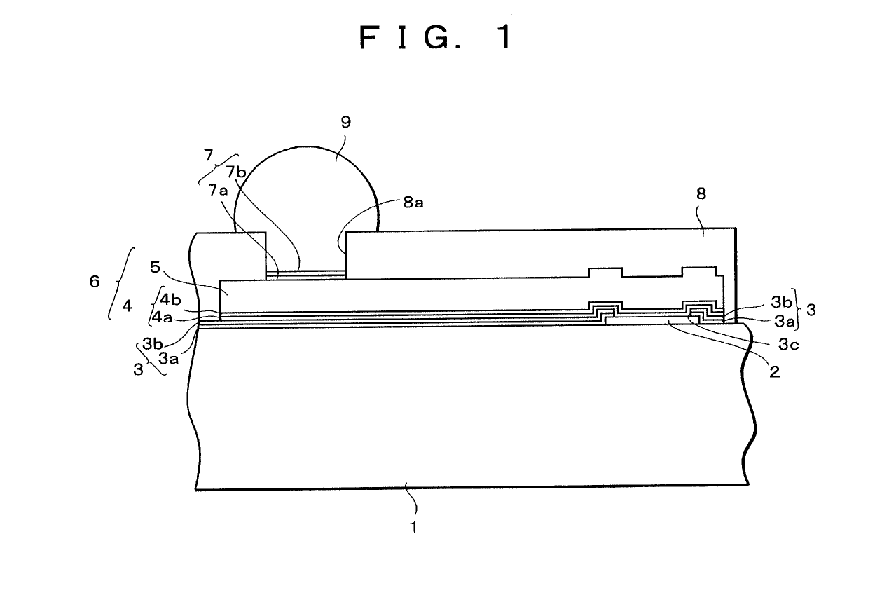

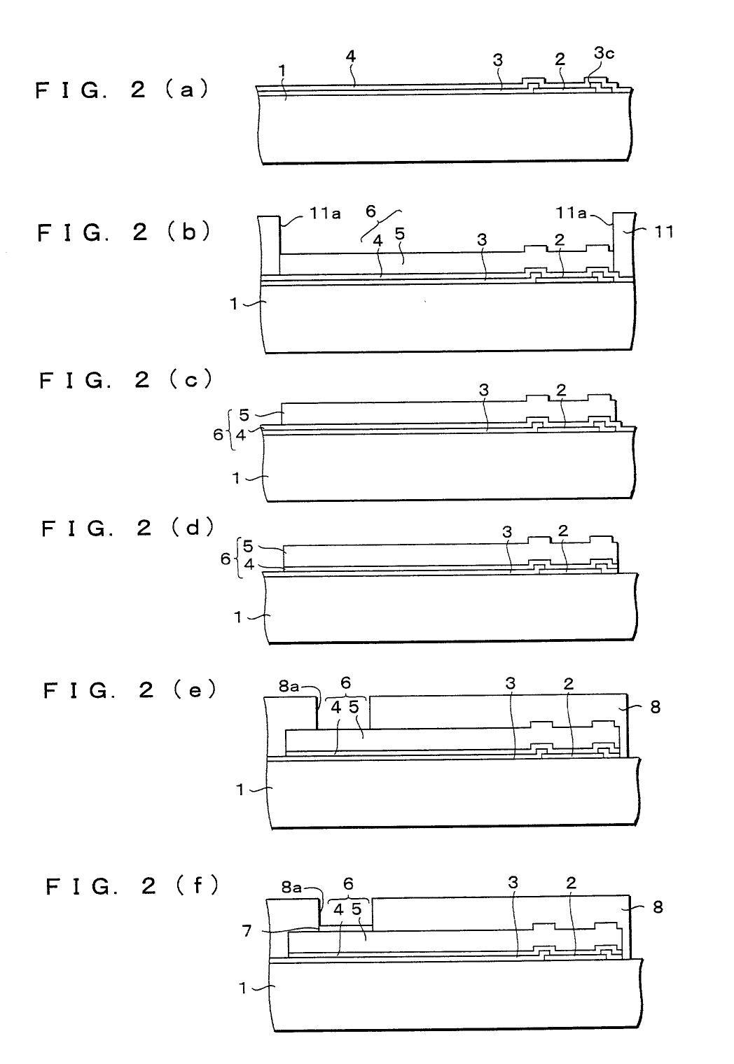

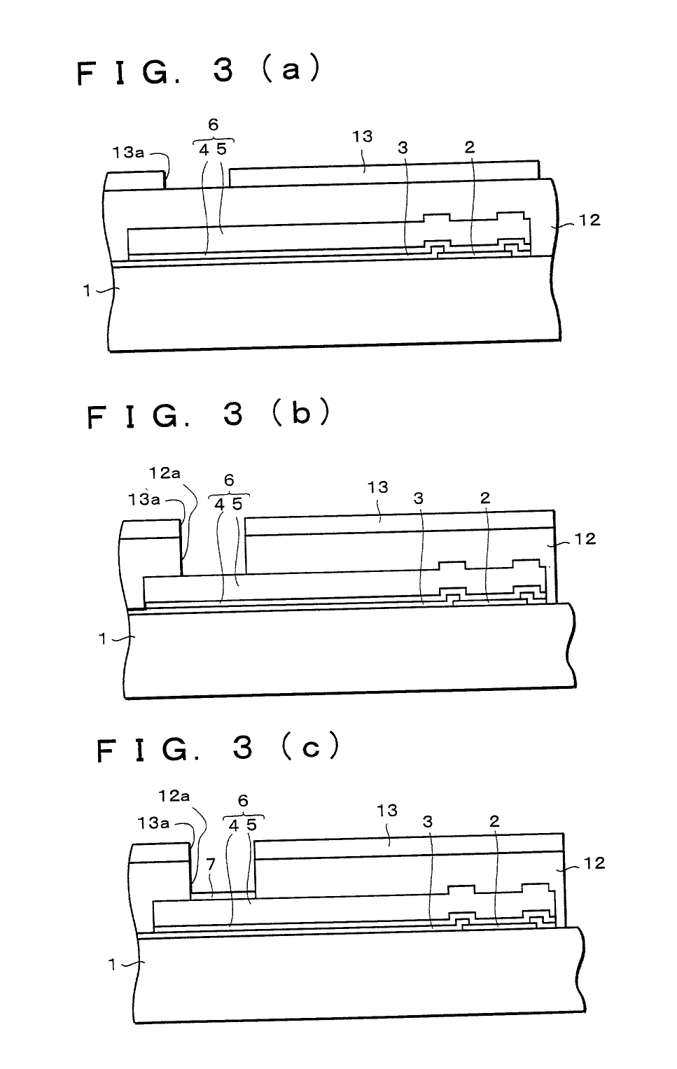

Explained below are embodiments of the present invention, with reference to FIG. 1 through FIGS. 8(a) to 8(d).

[First Embodiment]

The following describes a first embodiment of the present invention, referring to FIG. 1 to FIGS. 3(a) to 3(c).

FIG. 1 is a sectional view showing a structure of main sections of a semiconductor device. As shown in FIG. 1, the semiconductor device of the present embodiment is provided with, on a semiconductor substrate 1, an electrode pad 2, a first insulating layer 3, a wire 6, a third metal layer 7, a second insulating layer 8, and an external connection terminal 9.

On the semiconductor substrate 1, formed are the electrode pad 2, and the first insulating layer 3 having a first opening section 3c though which the electrode pad 2 is exposed. The wire 6 is made on the first insulating layer 3. The second insulating layer 8 covers the top and side surfaces of the wire 6. Moreover, the second insulating layer 8 has a second opening section 8a on the wire 6, while the external connection terminal 9, which is a protrudent electrode, is formed on a region of the wire 6 in the second opening section 8a.

A metal part of the electrode pad 2, being a metal made of Al or having Al as its main component, is disposed in a vicinity of a semiconductor element (not shown) on the semiconductor substrate 1. The first insulating layer 3 is formed all over the semiconductor substrate 1, except the region of the dicing line.

The first insulating layer 3 includes an inorganic passivation layer 3a and an organic passivation layer 3b. The inorganic passivation layer 3a is produced from inorganic raw materials, such as SiO₂. On the other hand, the organic passivation layer 3b, which is placed on the inorganic passivation layer 3a, is made of, for example, a non-photosensitive polyimide resin. In the semiconductor device of the present embodiment, drawbacks, such as crosstalk, is prevented by providing the organic passivation layer 3b.

Furthermore, provided on the first insulating layer 3 is the first opening section 3c for exposing the electrode pad 2 therethrough.

The wire 6 is disposed on the first insulating layer 3. The first opening section 3c of the first insulating layer 3 connects an end of the wire 6 to the electrode pad 2. Further, the wire 6 has the region disconnected from the electrode pad 2. To be used as a pad for connection to the external wire, a part of the region is exposed through the second opening section 8a. Note that, the wire 6 is structured with a first metal layer 4 as a foundation metal layer and a second metal layer 5, which is a main conductor layer formed thereon.

The first metal layer 4 has high adhesion with respect to the organic passivation layer 3b that is in contact with the bottom surface of the first metal layer 4. The first metal layer 4 is structured with a barrier metal layer 4a and an adhesion layer 4b. The barrier metal layer 4a is provided for suppressing diffusion of the metal structuring the second metal layer 5 that is in contact with the top surface of the first metal layer 4. The adhesion layer 4b gives higher adhesion between the second metal layer 5 and the first metal layer 4.

The barrier metal layer 4a is made of Ti—W, and located on the first insulating layer 3 and the electrode pad 2. The adhesion layer 4b is produced from Cu, and disposed on the barrier metal layer 4a. Meanwhile, the second metal layer 5 is formed with Cu of good conductivity, thereby giving the semiconductor device an ability to cope with a high speed.

Note that, the barrier metal layer 4a may be made of Ti—W, Ti, Cr or any metal having any of those elements as its main component. This allows the barrier metal layer 4a to have sufficient barrier properties with respect to the electrode pad 2.

On the top and side surfaces of the wire 6, formed is the second insulating layer 8, by using the photosensitive resin. The second insulating layer 8 is provided with the second opening section 8a on the wire 6. The second opening section 8a, which is located on the semiconductor element (not shown) positioned on the top surface of the wire 6, exposes the region located far from the electrode pad 2. The region in the second opening section 8a on the wire 6, has a circle shape of a 400 μm diameter, and used as the pad for connection with the external wire.

Moreover, the third metal layer 7 is formed on the region in the second opening 8a on the wire 6.

The third metal layer 7 is structured with a barrier metal layer 7a and a top layer 7b. The barrier metal layer 7a is made of Ni, and is provided for preventing interdiffusion of the Cu and the Au, of which the second metal layer 5 and the top layer 7b are made, respectively. At the same time, the barrier metal layer 7a contributes to junction with the metal including Sn.

Furthermore, the wire 6 is connected to the external connection terminal 9, which is made of an eutectic solder of Sn—Pb, via the third metal layer 7. The external connection terminal 9 has a top-view diameter of 450 μm, a size slightly larger than the second opening section Ba. This ensures sufficient availability of the metal structuring the prudent electrode that is to be offered to the second opening section 8a and a connection section of a mounting substrate, thereby attaining good connection reliability on regular basis.

The top layer 7b is produced from Au, which has good wetting properties with respect to the eutectic solder of Sn—Pb. This improves junction between the external connection terminal 9 and the metal layer 7, thereby contributing to the connection reliability.

Meanwhile, the gold (Au) forming the top layer 7b is 0.003 μm to 1 μm thick. The thickness range of the Au is set by reasons described below.

The junction between the external connection terminal 9 and the top layer 7b becomes fragile, because of excessive diffusion of Au into the eutectic solder of Sn—Pb, forming a fragile metal, in case of a thickness of the gold greater than 1 μm. Meanwhile, a thickness of the gold thinner than 0.003 μm causes poor wetting properties between the eutectic solder of Sn—Pb and the gold. Therefore, the thickness of the gold of the top layer 7b is preferred to be within the range.

By forming the third metal layer 7 in the second opening section 8a, no gap is produced between the second insulating layer 8 and wire 6 in the vicinity of the second opening section 8a, even if the top layer 7b of the third metal layer 7 is diffused into the external connection terminal 9, because the metal layer 7 is formed only in the opening section 8a. Therefore, prevented is the water condensation in the gap while the connection failure caused by the water condensation is also avoided. Thus, the connection reliability of the semiconductor device can be ensured.

It should be noted that, both of the inorganic passivation layer 3a and the organic passivation layer 3b are provided to structure the first insulating layer 3 of the present embodiment, but the first insulating layer 3 may be structured with either of them.

Furthermore, regarding the semiconductor device as a whole, formed on the semiconductor substrate 1 is a wire pattern that is to be connected to the semiconductor element. On the wire pattern, a plurality of the electrode pads 2 are formed at intervals. The electrode pats 2 are electrically connected to the wire pattern. Further, the first insulating layer 3 is formed on the wire pattern. Moreover, a plurality of the wires 6 are formed on the first insulating layer 3. The wires 6 have an end that is connected to the electrode pad 2 via the first opening section 3c. Moreover, the wires 6 detour so that they do not touch each other, and are connected to the external connection terminal 9.

Given below is an explanation on an example of a manufacturing process of the present embodiment, with reference to a process flow diagram shown in FIGS. 2(a) to 2(f).

To begin with, the inorganic passivation layer 3a is formed on the semiconductor substrate 1, where the electrode pad 2 of Al is formed. The inorganic passivation layer 3a is made of the inorganic raw materials, such as SiO₂. Applied thereon is the non-photosensitive polyimide resin of varnish-like texture. Then, the non-photosensitive polyimide resin is spread all over the semiconductor substrate 1, by spin coating. Thereafter, it is prebaked. Then, a photosensitive resist is applied and spread by spin coating, and again it is prebaked for temporally hardening the resist. After that, it is exposed to light by an exposure apparatus, and the temporally hardened polyimide resin is dissolved and removed by an alkaline developer of the resist, thus forming the first opening section 3c. Subsequently, the resist is removed by a peeling solution, then hardening of the polyimide resin is carried out at 350° C. for 1 hour, thereby the first insulating layer 3 is formed.

Next, the first metal layer 4 is formed over the entire surface of the semiconductor substrate 1 by spattering, in sequence that Ti—W is followed by Cu (FIG. 2(a)). Then, in a photosensitive resist 11, a resist opening section 11a is created, by a photolithography method, on the region where the electrode pads 2 and wires 6 are formed. Subsequently, the second metal layer 5 is formed in the resist opening section 11a by electroplating of Cu (FIG. 2(b)).

Thereafter, the resist 11 is peeled off (FIG. 2(c)), then wet etching is applied for removing the metals that structure the first metal layer 4, having the second metal layer 5 as a photo mask, in sequence that the copper (Cu) is removed first and then the titanium-tungsten (Ti—W) (FIG. 2(d)). This accomplishes the wires 6.

Hardening is carried out after the second insulating layer 8 is formed with a photosensitive resin, then, by the photolithography method, the second opening section 8a is created in the region where the external connection terminal 9 is made (FIG. 2(e)).

In the second opening section 8a on the second metal layer 5, the third metal layer 7 is formed by applying electroless plating of Ni and Au in sequence that Ni is followed by Au (Figure (f)). Subsequently, the external connection terminal 9 is created on the top layer 7b of Au by placing and melting the eutectic solder of Sn—Pb in the predetermined position.

Furthermore, where the substrate as a whole is a single IC, dicing is not necessary. But, there is a case that a plurality of ICs are formed on a single substrate, where the ICs are divided by dicing lines. In that case, in order to be separate semiconductor devices, the substrate can be simply cut out along the dicing lines after the external connection terminals 9 are created as described above.

In the above manufacturing method, the metal layer 7 is formed only in the second opening section 8a, by the step (1) of forming the second opening section 8a, which exposes the wire 6, in the region of the second insulating layer 8 which covers the top of the wire 6, and by the step (2) of forming the third metal layer 7 on the wire 6 in the second opening section 8a. This causes no gap formation between the second insulating layer 8 and the wire 6, even when the third metal layer 7, which includes Au having the good wetting properties with respect to the Su—Pb solder structuring the external connection terminal 9, is diffused into the external connection terminal 9, because the diffusion of the third metal layer 7 takes place only in the second opening section 8a. This prevents the water condensation in the gap formed between the second insulating layer 8 and wire 6, and avoids the connection failure caused by the water condensation. Therefore, the semiconductor device of the high connection reliability can be attained.

In the following, explained is an example of a manufacturing process where the second insulating layer 8 of the present embodiment is a second insulating layer 12 made of the non-photosensitive polyimide resin, with reference to process flow diagram shown in FIGS. 3(a) to 3(c). It should be noted that, the process has steps identical with those shown in FIGS. 2(a) and 2(b), which are up to the formation of the wires 6. Thus, the explanation for the corresponding steps are omitted, and the rest of the process is discussed, here.

Applied on the semiconductor substrate 1 is the non-photosensitive polyimide resin of varnish-like texture. Then, the non-photosensitive polyimide resin is spread all over the semiconductor substrate 1, by spin coating, so that the second insulating layer 12 is formed. Thereafter, it is prebaked for temporal hardening. Using a photosensitive resist, a resist opening section 13a is created by the photolithography method (FIG. 3(a)). After that, the temporally hardened polyimide resin is dissolved and removed by a developer of the resist 13, thus forming the second opening section 12a in the second insulating layer 12 (FIG. 3(b)).

Next, in the second opening section 12a on the second metal layer 5, the third metal layer 7 is formed by the electroless plating, first of Ni, then of Au (FIG. 3(c)) Here, the second insulating layer 12, which is covered with the resist 13, will not be polluted by being soaked in the chemicals, such as the plating solution, at the time the third metal layer 7 is formed.

Subsequently, the resist 13 is removed, then hardening of the second insulating layer 12 is carried out at 350° C. for one hour.

Finally, the external connection terminal 9 is created on the top layer 7b, which is made of Au, by placing and melting the eutectic solder of Sn—Pb in the predetermined position.

With the above manufacturing method, as the previously discussed manufacturing method, this causes no gap formation between the second insulating layer 8 and the wire 6, thus preventing the water condensation in the gap formed between the second insulating layer 8 and the wire 6. Without water condensation that causes connection failure, the semiconductor device of the high connection reliability can be attained.

Moreover, the step of removing the resist 13 is employed after the step of forming the third metal layer 7 in the second opening section 12a on the wire 6. This allows the second insulating layer 12 to be covered with the resist 13 at the time of the formation of the third metal layer 7. This protects the second insulating layer 12 from being polluted by being soaked in the chemicals, such as the plating solution, at the time the third metal layer 7 is formed.

[Second Embodiment]

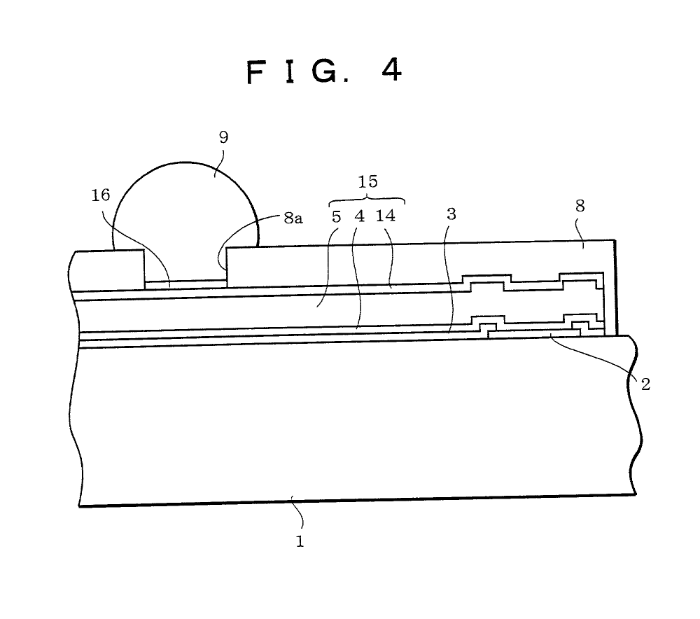

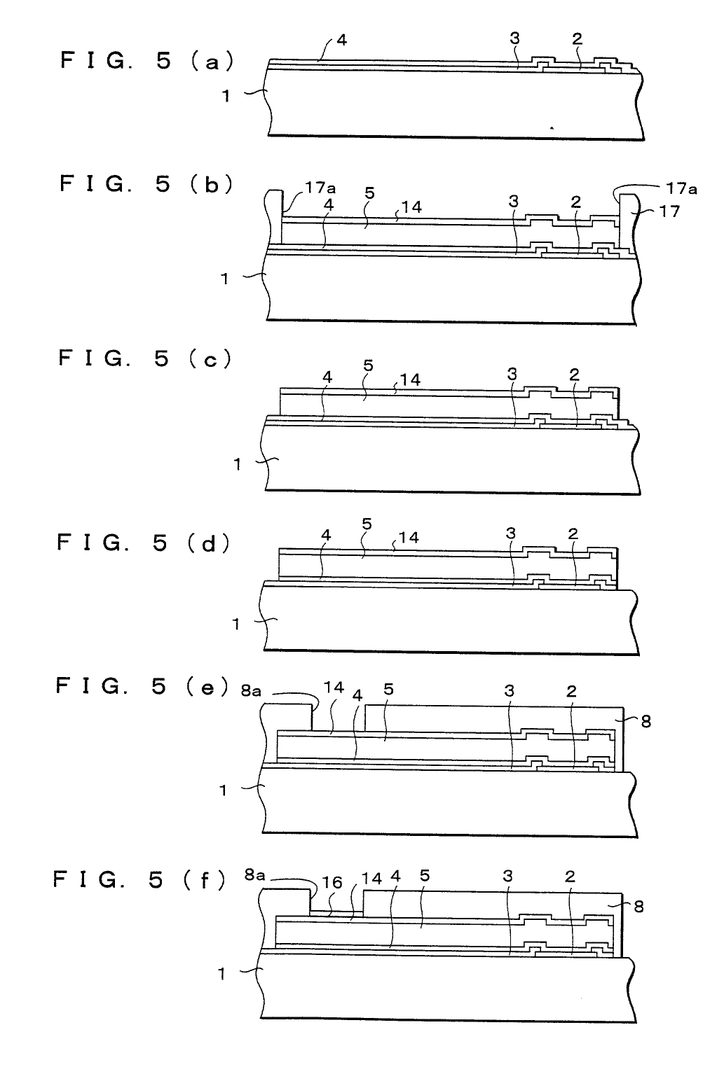

Described below is a second embodiment of the present invention, with reference to FIGS. 4 to FIGS. 8(a) to 8(d). It should be noted that, sections having functions identical with the corresponding sections of the first embodiments are numbered in the same fashion, and their explanation is omitted, here.

FIG. 4 is a sectional view showing a structure of main sections of a semiconductor device of a second embodiment of the present invention. The semiconductor device of the present embodiment is provided, as shown in FIG. 4, with an electrode pad 2, a first insulating layer 3, a second insulating layer 8, and an external connection terminal 9 on a semiconductor substrate 1, just like the first embodiment. Meanwhile, the semiconductor device of the present embodiment includes a wire 15 and a third metal layer 16, which are not identical with the corresponding sections of the first embodiment.

The wire 15 is structured with a first metal layer 4, a second metal layer 5, and a fourth metal layer 14. The fourth metal layer 14, which is formed so as to cover the top surface of the second metal layer 5, is made of a raw materials different from that of the second metal layer 5, such as Ni. Note that, the fourth metal layer 14 shows little reactivity with resin made of, for example, the polyimide that structures the second insulating layer 8, meanwhile the fourth metal layer 14 can be sufficiently adhered with resins such as polyimide.

The third metal layer 16, which is formed in the second opening section 8a on the wire 15, is made of Au. In the present embodiment, where the fourth metal layer 14 of Ni covers the top of the second metal layer 5, interdiffusion of the copper (Cu) of the second metal layer 5 and the gold (Au) of the third metal layer 16 can be prevented without providing a nickel layer as the third metal layer 16, as the first embodiment. Again, because no nickel layer as the third metal layer 7 is necessary (see FIG. 1), the thickness of the third metal layer 16 can be thinner than the third metal layer 7 of the first embodiment (see FIG. 1).

Given below is an explanation on an example of a manufacturing process of the present embodiment, with reference to FIGS. 5(a) through 5(f). It should be noted that, the process has steps identical with those of the first embodiment up to the step shown in FIG. 2(a), where the first insulating layer 3 is formed, thus its explanation is omitted and the rest of the steps are discussed here.

After the first insulating layer 3 is formed, the first metal layer 4 is formed all over the semiconductor substrate 1 by spattering, where Ti—W is applied first, then Cu (FIG. 5(a)). By employing the photolithography method that uses the photosensitive resist 17, a resist opening section 17a is created on the region where the electrode 2 and the wire 15 are formed. Subsequently, the second metal layer 5 is formed by performing electroplating of Cu in the resist opening section 17a. Further, on the second metal layer 5, electroplating of NI is carried out for forming the fourth metal layer 14 (FIG. 5(b)). Here, the electroplating of Ni is possible because the first insulating layer 3 is formed on the entire surface of the semiconductor substrate 1.

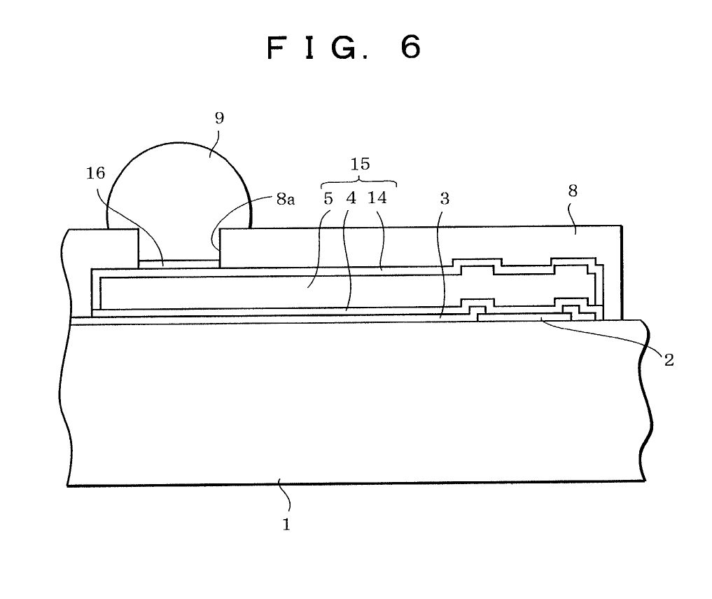

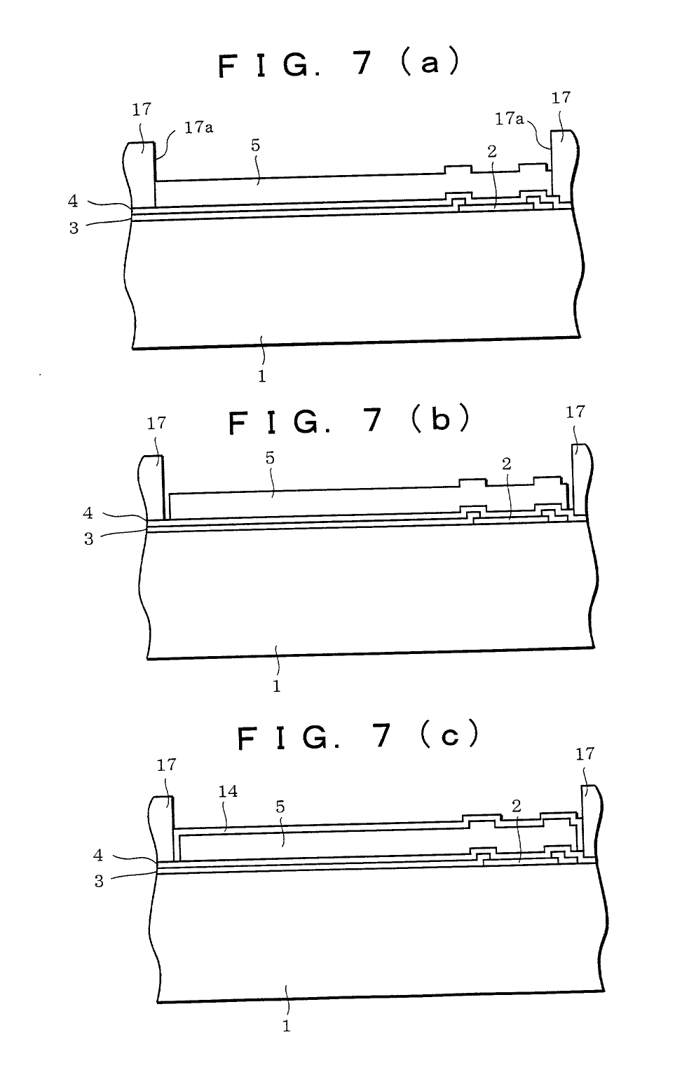

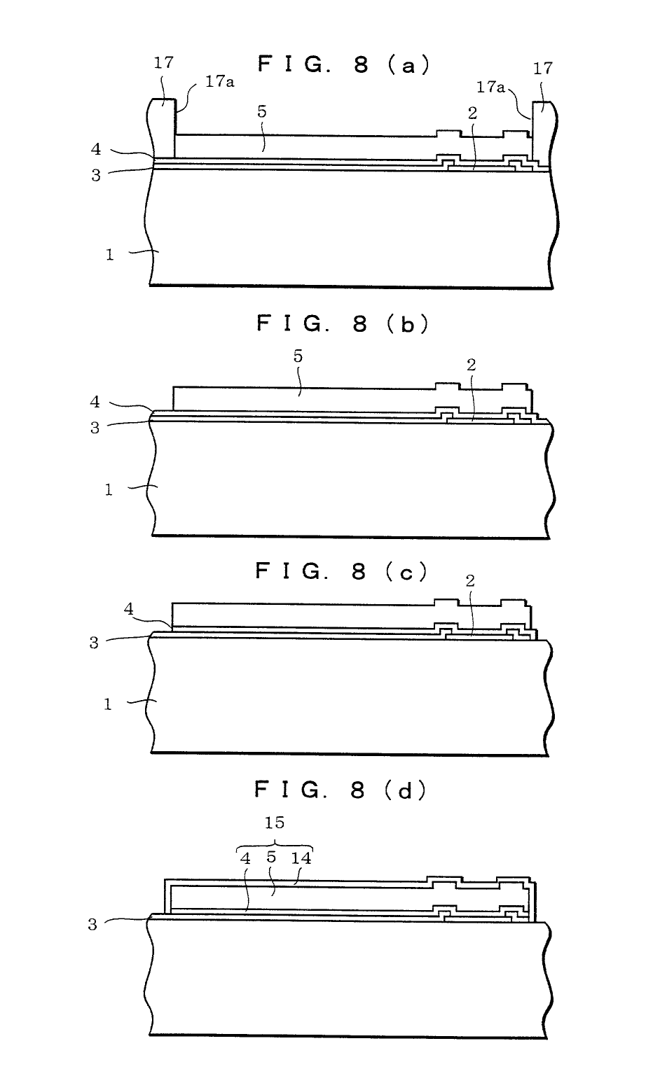

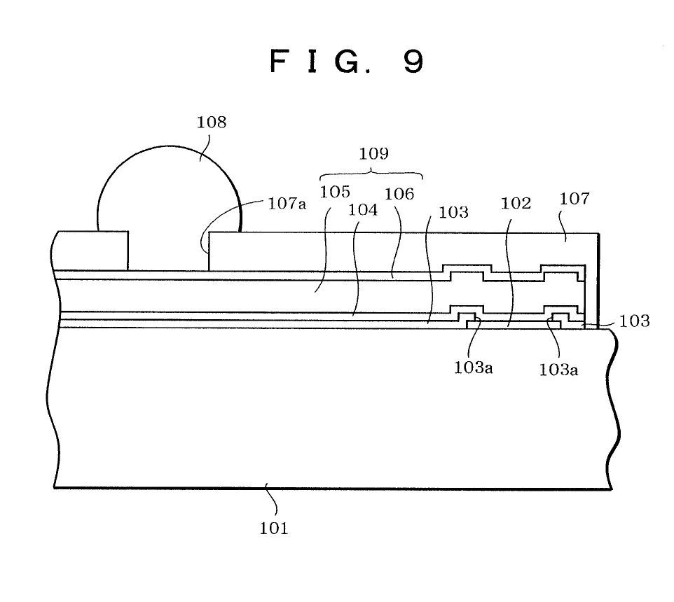

Thereafter, the resist 17 is peeled off (FIG. 5(c)), and the metals structuring the first metal layer 4 are removed by wet etching in a sequence that Cu is firstly removed, then Ti—W, where the second metal layer 5 and the fourth metal layer 14 are used as photo masks (FIG. 5(d)). This accomplishes the wire 15, as shown in FIG. 6, which is provided with the first metal layer 4, the second metal layer 5, and the fourth metal layer 14.

The second insulating layer 8 is formed with the photosensitive polyimide resin, then the second opening section Ba is created in the region for providing the external connecting terminal 9, by employing the photolithography method. After that, hardening is performed at 350° C. for one hour (FIG. 5(e)).

The third metal layer 16 is formed by electroless plating of Au in the second opening section 8a on the fourth metal layer 14 (FIG. 5(f)). Then, the external connection terminal 9 is created on the third metal layer 15, which is made of Au, by placing and melting the eutectic solder of Sn—Pb in the predetermined position.

With the above manufacturing method, the third metal layer 16 can be formed only in the second opening section 8a, as the first embodiment. This causes no gap formation between the second insulating layer 8 and the wire 15, even when the third metal layer 16, which includes Au having the good wetting properties with respect to the Su—Pb solder structuring the external connection terminal 9, is diffused into the external connection terminal 9, because the diffusion of the third metal layer 16 takes place only in the second opening section 8a. This prevents the water condensation in the gap formed between the second insulating layer 8 and wire 15, and avoids the connection failure caused by the water condensation. Therefore, the semiconductor device of the high connection reliability can be attained. Furthermore, the thickness of the third metal layer 16 can be thinner, so that stress load on the side wall of the second opening section 8a can be reduced at the time of the electroless plating of Au in the second opening section 8a, and exfoliation and crack of the second insulating layer 8 can be prevented.

Note that, photosensitive resins apart from the polyimide type can be used as the second insulating layer 8, while the polyimide resin is used in the present embodiment.

Again, the third metal layer 16 can be formed with Ni and Au. The electroless plating of Ni provides good adhesion between the third metal layer 16 and the fourth metal layer 14.

Moreover, as shown in FIG. 6, the fourth metal layer 14 may cover not only the top surface of the second metal layer 5, but also its side surfaces.

Here, described below is an example of a manufacturing process of the present embodiment, where the top and side surfaces of the second metal layer 5 is coated with the fourth metal layer 14, with reference to FIGS. 7(a) through 7(c). Note that, the manufacturing process has a step identical with that of the manufacturing process discussed earlier, up to FIG. 5(a) where the first metal layer 4 is formed. Thus, the explanation on the step is not repeated, and the rest of the steps are discussed, here.

The photolithography method is employed by use of the photosensitive resist 17 for creating the resist opening section 17a on the region where the electrode pad 2 and the wire 15 are formed. Then, in the resist opening section 17a, electroplating of Cu is applied for forming the second metal layer 5 (FIG. 7 (a)). Thereafter, the resist 17 is exposed to light and developed again. Here, the exposure mask is prepared to have slightly greater width than the width of the second metal layer 5. A space is produced around the second metal layer 5 in the above manner (FIG. 7(b)).

Furthermore, the fourth metal layer 14 is formed on the top and side surfaces of the second metal layer 5 by the electroplating of Ni (FIG. 7(c)).

The remaining steps are identical with the steps shown in FIGS. 5(c) to 5(f) with respect to the process flow diagram of the semiconductor device discussed previously. Thus, their explanation is omitted, here.

With the manufacturing method, as the semiconductor device discussed previously, the top and side surfaces of the second metal layer 5 can be covered with the fourth metal layer 14 made of Ni. This causes no gap formation between the second insulating layer 8 and the wire 15, even when the third metal layer 16 is diffused into the external connection terminal 9, because the third metal layer 16 is formed only in the second opening section 8a. This prevents the water condensation in the gap formed between the second insulating layer 8 and wire 15, and avoids the connection failure caused by the water condensation. Therefore, the semiconductor device having the high connection reliability can be attained. Furthermore, the thickness of the third metal layer 16 can be thinner, so that stress load on the side wall of the second opening section 8a can be reduced at the time of the electroless plating of Au in the second opening section 8a, and exfoliation and crack of the second insulating layer 8 can be prevented.

Furthermore, described below is another example of a manufacturing process of the present embodiment where the top and side surfaces of the second metal layer 5 are covered with the fourth metal layer 14, with reference to FIGS. 8(a) through 8(d). Note that, the manufacturing process has a step identical with the step of the process flow diagram of the above semiconductor device, up to FIG. 5(a) where the first metal layer 4 is formed. Thus, an explanation on the step is omitted and the rest of the process is discussed, here.

The photolithography method is carried out by use of a photosensitive resist 17 for creating a resist opening section 17a on the region where the electrode pad 2 and a wire 15 are formed. Then, the electroplating of Cu is performed in the resist opening section 17a, so that the second metal layer 5 is formed (FIG. 8(a)).

Thereafter, the resist 17 is peeled off (FIG. 8(b)), then the metal structuring the first metal layer 4 is removed by the wet etching where the second metal layer 5 is used as a photo mask, in sequence that the copper is removed first, then the Titanium-Tungsten, secondly (FIG. 8(c)). Further, electroless plating of Ni is applied on the second metal layer 5 so that a fourth metal layer 14 of a 3 μm thickness is formed, thus accomplishing the wire 15 (FIG. 8(d)).

The remainder of the process is same as the steps shown in FIGS. 5(e) and 5(f) with respect to the process flow diagram of the semiconductor device, thus their explanation is omitted, here.

Also with the manufacturing method, as the semiconductor device discussed previously, by covering the top and side surfaces of the second metal layer 5 with the fourth metal layer 14 made of Ni, it is possible to prevent the water condensation in the gap formed between the second insulating layer 8 and the wire 15, which may cause the connection failure, and exfoliation and cracks of the second insulating layer 8. Therefore, the semiconductor device having the high connection reliability can be attained.

In the semiconductor device, it is preferable that the protrudent electrode is made of Sn or a metal having Sn as its main component, and the metal layer is made of Au or a metal having Au as its main component.

With the above arrangement, the protrude electrode is made of Sn or the metal having Sn as its main component, while the metal layer is made of Au or the metal having Au as its main component. This gives the protrudent electrode good wetting properties, thereby adhesion of the protrudent electrode is better, compared to a case where the metal layer, which is in contact with the protrudent electrode, is made of a metal in the platinum group.

In the semiconductor device, it is preferable that the metal layer has a thickness ranging from 0.003 μm to 1 μm.

With the above arrangement, the range of the thickness of the metal layer from 0.003 μm to 1 μm can prevent the protrudent electrode from being fragile due to excessive diffusion of Au at the junction between the protrudent electrode and the metal layer. Meanwhile, it provides sufficient adhesion between the protrudent electrode and the metal layer, thus facilitating the junction between them.

It is preferable that the semiconductor device has a protrudent electrode that is formed in such a manner that a part of the protrudent electrode, which is protrudent from the opening section, is larger than an area of the opening section.

The above arrangement ensures the sufficient availability of the metal structuring the prudent electrode that is to be offered to the opening section and the connection section of the mounting substrate, thereby attaining the good connection reliability on the regular basis.

In the semiconductor device, it is preferable that the protrudent electrode is made of Sn or a metal having Sn as its main component, and the metal layer including a nickel layer and a gold layer, the nickel layer being made of Ni or a metal having Ni as its main component by the electroless plating, and the gold layer being made of Au or a metal having Au as its main component and being on the nickel layer.

With the above arrangement, where the gold layer is the metal layer in contact with the protrudent electrode, the protruden: electrode can attain good wetting properties, thereby adhesion of the protrudent electrode is better, compared to a case where the metal layer, which is in contact with the protrudent electrode, is made of a metal in the platinum group. Meanwhile, the nickel layer prevents diffusion of Au.

In the semiconductor device, it is preferable that the main conductor layer is made of Cu or a metal having Cu as its main component.

With the above arrangement, where the main conductor layer is made of Cu or the metal having Cu as its main component, the main conductor layer attains high conductivity, thereby giving the semiconductor device an ability to cope with high speed.

An semiconductor device is preferably provided with a barrier metal layer made of Ni or a metal having Ni as its main component, on an entire top surface of the main conductor layer.

In the above arrangement, provided is the barrier metal layer all over the top surface of the main conductor layer. The barrier metal layer is made of Ni or the metal having Ni as its main component. This ensures separation between the metal layer and the main conductor layer. Meanwhile, this suppresses the reaction between the main conductor layer and the insulating layer, thereby preventing deterioration of characteristics of the insulating layer. Further, this eliminates needs of providing the nickel layer to the metal layer, thus reducing the thickness of the metal layer.

In the semiconductor device, it is preferable that the barrier metal layer covers side surfaces of the main conductor layer.

With the above arrangement, where the barrier metal layer covers not only the entire tope surface of the conductor layer, but also the side surfaces of the main conductor layer, the reaction between the main conductor layer and the insulating layer can be prevented. Meanwhile, this ensures the prevention of the deterioration of the characteristics of the insulating layer.

An semiconductor device is preferably further provided with a foundation metal layer made of Ti, TiW, Cr, or a metal having any of those elements as its main component, under the main conductor layer.

With the above arrangement, the interdiffusion of the metals can be prevented by providing, under the main conductor layer, the foundation metal layer made of Ti, Ti—W, Cr or a metal having any of those elements as its main component. This allows the foundation metal layer to have an ability to be a sufficient barrier against the electrode pad.

It is preferable that a manufacturing method of a semiconductor device further includes the step of enlarging the first resist opening sections by carrying out exposure by use of a mask pattern, and the step of forming a barrier metal layer in the enlarged first resist opening sections, after the step of forming the main conductor layer.

With the above arrangement, the top and side surfaces of the main conductor layer are covered with the barrier metal layer by forming the barrier metal layer in the enlarged first resist opening sections. Thereby, prevented is a reaction between the main conductor layer and the second insulating layer. Meanwhile, the deterioration of the characteristics of the second insulating layer can be prevented.

It is preferable that a manufacturing method of the semiconductor device further includes the step of forming a metal layer on the main conductor layer by electroless plating of a raw material different from the main conductor layer, after the step of removing the foundation metal layer.

While step of forming the opening section requires high accuracy in positioning, in the above arrangement, the step is carried out only once. Thus, it is easy to form even a wire pattern with a refined pattern.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

Whet is claimed is:

1. A semiconductor device, comprising:
a main conductor layer having an end that is electrically connected to an electrode pad;
an insulating layer having an opening section on said main conductor layer; and
a protrudent electrode electrically connected to said main conductor layer via said opening section,
said semiconductor device, further comprising:
a metal layer provided on the main conductor layer in the opening section so that said metal layer is provided between said main conductor layer and said protrudent electrode.

2. The semiconductor device as set forth in claim 1, wherein:
said protrudent electrode is made of Sn or a metal having Sn as its main component; and
said metal layer is made of Au or a metal having Au as its main component.

3. The semiconductor device as set forth in claim 2, wherein said metal layer has a thickness ranging from 0.003 μm to 1 μm.

4. The semiconductor device as set forth in claim 1, wherein said protrudent electrode is made of Sn or a metal having Sn as its main component, and said metal layer including a nickel layer and a gold layer,
said nickel layer being made of Ni or a metal having Ni as its main component, by electroless plating; and
said gold layer being made of Au or a metal having Au as its main component.

5. The semiconductor device as set forth in claim 4, wherein said gold layer has a thickness ranging from 0.003 μm to 1 μm.

6. The semiconductor device as set forth in claim 1, wherein said protrudent electrode is formed so that said protrudent electrode has a part, which protrudes from said opening section, of a size greater than an area of said opening section.

7. The semiconductor device as set forth in claim 1, wherein said main conductor layer is made of Cu or a metal having Cu as its main component.

8. An semiconductor device as set forth in claim 1, further comprising:
a barrier metal layer made of Ni or a metal having Ni as its main component, on an entire top surface of said main conductor layer.

9. The semiconductor device as set forth in claim 8, wherein said barrier metal layer covers side surfaces of said main conductor layer.

10. An semiconductor device as set forth in claim 1, further comprising:
a foundation metal layer made of Ti, Ti—W, Cr, or a metal having any of those elements as its main component, under said main conductor layer.

11. A manufacturing method of a semiconductor device, comprising the steps of:
forming a foundation metal layer on a semiconductor substrate on which formed are a plurality of electrode pads and a first insulating layer having first opening sections on said electrode pads;
forming a photosensitive first resist on said foundation metal layer;
forming, in said first resist, a plurality of first resist opening sections for exposing said electrode pads;
forming a main conductor layer in said first resist opening sections;
removing said first resist;
removing said foundation metal layer by use of said main conductor layer as a photo mask;
forming a photosensitive second insulating layer so that said second insulating layer covers said first insulating layer and said main conductor layer;
forming second opening sections in regions of said second insulating layer, which covers the top surface of said main conductor layer, so that said main conductor layer is exposed therethrough;
forming a metal layer on main conductor layer in said second opening sections; and
forming protrudent electrodes on said metal layer.

12. A manufacturing method of a semiconductor device as set forth in claim 11, further comprising the steps of:
enlarging said first resist opening sections by carrying out exposure by use of a mask pattern, after the step of forming said main conductor layer; and
forming a barrier metal layer in said enlarged first resist opening sections.

13. A manufacturing method of a semiconductor device as set forth in claim 11, further comprising the step of:
forming a metal layer on said main conductor layer by electroless plating of a raw material different from said main conductor layer, after the step of removing said foundation metal layer.

14. A manufacturing method of a semiconductor device, comprising the steps of:
forming a foundation metal layer on a semiconductor substrate on which formed are a plurality of electrode pads and a first insulating layer having first opening sections on said electrode pads;
forming a photosensitive first resist on said foundation metal layer;
forming, in said first resist, a plurality of first resist opening sections for exposing said electrode pads;
forming a main conductor layer in said first resist opening sections;
removing said first resist;
removing said foundation metal layer by use of said main conductor layer as a photo mask;
forming a second insulating layer so that said second insulating layer covers said first insulating layer and said main conductor layer;
forming a second resist on said second insulating layer;
forming, in said second resist, a plurality of second resist opening sections for exposing said main conductor layer;
forming second opening sections in regions of said second insulating layer, which covers a top surface of said main conductor layer, by use of said second resist as a photo mask, so that said main conductor layer is exposed therethrough;
forming a metal layer on said main conductor layer in said second opening sections;
removing said second resist; and
forming protrudent electrodes on said metal layer.

15. A manufacturing method of a semiconductor device as set forth in claim 14, further comprising the steps of:
enlarging said first resist opening sections by carrying out exposure by use of a mask pattern, after the step of forming said main conductor layer; and
forming a barrier metal layer in said enlarged first resist opening section.

16. A manufacturing method of a semiconductor device as set forth in claim 14, further comprising the step of:
forming a metal layer on said main conductor layer by electroless plating of a raw material different from said main conductor layer, after the step of removing said foundation metal layer.
